(19) United States
(12) Patent Application Publication
(10) Pub. No.: US 2024/0369732 A1
(43) Pub. Date: Nov. 7, 2024

(54) ELECTRONIC CONTROL UNIT AND METHOD FOR DETERMINING SUBSTANCE FLOWED INTO ELECTRONIC CONTROL UNIT

(71) Applicant: HL MANDO CORPORATION, Gyeonggi-do (KR)

(72) Inventor: Hanjun LEE, Gyeonggi-do (KR)

(21) Appl. No.: 18/401,343

(22) Filed: Dec. 30, 2023

(30) Foreign Application Priority Data
May 3, 2023 (KR) 10-2023-0057796
Aug. 29, 2023 (KR) 10-2023-0113890

(51) Int. Cl. G01V 3/02; H05K 7/14

(52) U.S. Cl. CPC G01V 3/02; H05K 7/1427

(57) ABSTRACT

An electronic control unit includes a housing, a circuit board installed inside the housing and including a first pattern and a second pattern that is spaced apart from the first pattern by a predetermined interval and disposed parallel to the first pattern, and a controller mounted on the circuit board, wherein the controller may control a voltage output of the first pattern based on a determination of an inflow of a substance into the housing, monitor a voltage of a circuit electrically connected to the second pattern while controlling the voltage output of the first pattern, and determine a type of the substance based on data obtained from the monitoring and output corresponding information.

### CROSS-REFERENCE TO RELATED APPLICATION

This application claims the priority to and benefit of Korean Patent Application No. 10-2023-0057796 filed on May 3, 2023 and No. 10-2023-0113890 filed on Aug. 29, 2023 in the Korean Intellectual Property Office, the disclosure of which is incorporated herein by reference in its entirety.

### BACKGROUND

### 1. Field

The present disclosure relates to an electronic control unit and a method for determining a substance flowed into the electronic control unit.

### 2. Description of the Related Art

Vehicle electrical systems are changing to an electronic form with the expansion of electric vehicles, and with this change, the importance of functional safety is increasing.

In particular, a detection function for the inflow of a substance (e.g., liquid) into an electronic control unit (ECU) of the electrical system may be deemed an important part in the functional safety of a vehicle.

When liquid is flowed into the electronic control unit, an electronic short-circuit may occur, which may cause fatal defects in the electronic control unit. In addition, the inflow of liquid into the electronic control unit may cause an internal fire and a battery failure of the vehicle, which may greatly affect the safety of the vehicle.

Accordingly, in recent years, a design that allows detection of liquid flowed into an electronic control unit is required when designing a vehicle electrical system.

Conventionally, the Karl Fischer technique has been developed as a chemical analysis technique for liquid detection. However, when applying this technique to an electronic control unit, an additional circuit is required and a cost increase problem occurs.

Thus, conventionally, a technique, in which the presence or absence of liquid entering an electronic control unit is detected by disposing a detection pattern on the outside of a printed circuit board (PCB) of the electronic control unit and utilizing the principle that a resistive component is generated when the detection pattern comes into contact with the liquid, is applied.

However, such a conventional technique can only determine whether liquid has flowed into the electronic control unit, and it has been difficult to identify a root cause of the inflow of liquid into the electronic control unit.

Only when the root cause of the inflow of liquid into the electronic control unit is identified, vehicle accident due to defects and problems of the electrical system can be prevented.

Accordingly, in order to identify the root cause of the inflow of liquid into the electronic control unit, it is necessary to determine the type of inflow liquid when the liquid has flowed into the electronic control unit.

However, no technology has been developed to determine the type of liquid, i.e., substance, that has flowed into the electronic control unit.

### SUMMARY

One aspect of the disclosed disclosure may provide an electronic control unit of a vehicle capable of determining an inflow of a substance into the electronic control unit and the type of substance flowed into the electronic control unit, and a method for determining a substance flowed into the electronic control unit.

In accordance with one aspect of the present disclosure, an electronic control unit includes a housing, a circuit board installed inside the housing and including a first pattern and a second pattern that is spaced apart from the first pattern by a predetermined interval and disposed parallel to the first pattern, and a controller mounted on the circuit board, wherein the controller may control a voltage output of the first pattern based on a determination of an inflow of a substance into the housing, monitor a voltage of a circuit electrically connected to the second pattern while controlling the voltage output of the first pattern, and determine a type of the substance based on data obtained from the monitoring and output corresponding information.

The electronic control unit may further include a memory configured to store reference data on at least one of a reference voltage level corresponding to each of a plurality of predetermined substances or a spectrum of the reference voltage level, wherein the controller may determine the type of the substance based on the reference data stored in the memory.

The controller may monitor the voltage of the circuit electrically connected to the second pattern, while controlling the voltage output of the first pattern such that a voltage of the first pattern is sequentially increased to a predetermined first voltage value and then sequentially decreased to a predetermined second voltage value.

The controller may monitor the voltage of the circuit electrically connected to the second pattern while controlling the voltage of the first pattern such that a frequency of the voltage of the first pattern is sequentially increased to a predetermined range by controlling the voltage output of the first pattern.

The controller may obtain a voltage level of the circuit electrically connected to the second pattern from the monitoring, and determine the type of the substance based on the voltage level of the circuit electrically connected to the second pattern.

The controller may generate a spectrum of the voltage level of the circuit electrically connected to the second pattern, and determine the type of the substance based on the spectrum.

The controller may control such that the first pattern outputs a voltage of a predetermined magnitude based on the supply of power from a power supply, and monitor whether the voltage of the circuit electrically connected to the second pattern is greater than or equal to a predetermined reference voltage while controlling such that the first pattern outputs the voltage of the predetermined magnitude, and determine that the substance has flowed into the housing when the voltage of the circuit electrically connected to the second pattern is greater than or equal to the predetermined reference voltage.

The voltage of the circuit electrically connected to the second pattern may be triggered by a resistance that is formed between the first pattern and the second pattern according to the inflow of the substance into the housing.

The first pattern may be electrically connected to a first power supply line of a power source, the controller may be electrically connected to a second power supply line of the power source and the second pattern, a pull-down circuit may be connected between the controller and the second pattern, and the circuit may include the pull-down circuit.

Each of the first pattern and the second pattern may include a linear pattern extending in a first direction along an edge of the circuit board.

The type of the substance may include at least one of salt water, water, washer fluid, or brake oil.

In accordance with another aspect of the present disclosure, a method for determining a substance flowed into an electronic control unit includes controlling a voltage output of a first pattern disposed on a circuit board inside a housing based on a determination of an inflow of a substance into the housing of the electronic control unit, monitoring, while controlling the voltage output of the first pattern, a voltage of a circuit electrically connected to a second pattern that is disposed on the circuit board to be spaced apart from the first pattern by a predetermined interval and disposed parallel to the first pattern, and determining a type of the substance based on data obtained from the monitoring and outputting corresponding information.

In the determining of the type of the substance, reference data on at least one of a reference voltage level corresponding to each of a plurality of predetermined substances or a spectrum of the reference voltage level may be further referenced.

The monitoring of the voltage of the circuit electrically connected to the second pattern disposed on the circuit board may be performed while controlling the voltage output of the first pattern such that a voltage of the first pattern is sequentially increased to a predetermined first voltage value and then sequentially decreased to a predetermined second voltage value.

The monitoring of the voltage of the circuit electrically connected to the second pattern disposed on the circuit board may be performed while controlling a frequency of the voltage of the first pattern such that the frequency of the voltage of the first pattern is sequentially increased to a predetermined range by controlling the voltage output of the first pattern.

The determining of the type of the substance may include obtaining a voltage level of the circuit electrically connected to the second pattern from the monitoring, and determining the type of the substance based on the voltage level of the circuit electrically connected to the second pattern.

The method for determining a substance flowed into an electronic control unit may further include generating a spectrum of the voltage level of the circuit electrically connected to the second pattern, wherein, in the determining of the type of the substance, the spectrum may be further referenced.

The method for determining a substance flowed into an electronic control unit may further include controlling such that the first pattern outputs a voltage of a predetermined magnitude based on the supply of power from a power supply, monitoring whether the voltage of the circuit electrically connected to the second pattern is greater than or equal to a predetermined reference voltage while controlling such that the first pattern outputs the voltage of the predetermined magnitude, and determining that the substance has flowed into the housing when the voltage of the circuit electrically connected to the second pattern is greater than or equal to the predetermined reference voltage.

The voltage of the circuit electrically connected to the second pattern may be triggered by a resistance that is formed between the first pattern and the second pattern according to the inflow of the substance into the housing.

The first pattern may be electrically connected to a first power supply line of a power source, the controller may be electrically connected to a second power supply line of the power source and the second pattern, a pull-down circuit may be connected between the controller and the second pattern, and the circuit may include the pull-down circuit.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a block diagram of a vehicle in accordance with one embodiment of the present disclosure;

FIG. 2 is a diagram illustrating a first pattern and a second pattern on a circuit board in accordance with one embodiment of the present disclosure;

FIG. 3 is a diagram illustrating a circuit configuration of an electronic control unit in accordance with one embodiment of the present disclosure;

FIG. 4 is a diagram illustrating a first test pattern and a second test pattern on a test circuit board in accordance with one embodiment of the present disclosure;

FIGS. 5 and 6 are diagrams each illustrating voltage waveforms on a circuit electrically connected to the second test pattern for each substance when a reference voltage of a predetermined magnitude is applied to the first test pattern on the test circuit board in accordance with one embodiment of the present disclosure;

FIG. 7 is a diagram illustrating voltage waveforms on the circuit electrically connected to the second test pattern for each of a plurality of substances upon controlling the voltage magnitude of the first test pattern on the test circuit board in accordance with one embodiment of the present disclosure;

FIG. 8 is a diagram illustrating a spectrum for each of the plurality of substances upon controlling a voltage frequency of the first test pattern on the test circuit board in accordance with one embodiment of the present disclosure; and

FIG. 9 is a flowchart of an operation of the electronic control unit in accordance with one embodiment of the present disclosure.

### DETAILED DESCRIPTION

Like reference numerals refer to like components throughout the specification. This specification does not describe all the components of the embodiments, and duplicative contents between embodiments or general contents in the technical field of the present disclosure will be omitted. The terms ‘part,’ ‘module,’ ‘member,’ and ‘block’ used in this specification may be embodied as software or hardware, and it is also possible for a plurality of ‘parts,’ ‘modules,’ ‘members,’ and ‘blocks’ to be embodied as one component, or one ‘part,’ ‘module,’ ‘member,’ and ‘block’ to include a plurality of components according to embodiments.

Throughout the specification, when a part is referred to as being ‘connected’ to another part, it includes not only a direct connection but also an indirect connection, and the indirect connection includes connecting through a wireless network.

Also, when it is described that a part ‘includes’ a component, it means that the part may further include other components, not excluding the other components unless specifically stated otherwise.

Throughout the specification, when a member is described as being ‘on’ another member, this includes not only a case in which the member is in contact with the other member but also a case in which another member is present between the two members.

The terms first, second, etc. are used to distinguish one component from another component, and the components are not limited by the above-mentioned terms.

The singular forms ‘a,’ ‘an,’ and ‘the’ include plural referents unless the context clearly dictates otherwise.

In each operation, an identification numeral is used for convenience of explanation, the identification numeral does not describe the order of the operations, and each operation may be performed differently from the order specified unless the context clearly states a particular order.

Hereinafter, an operation principle and embodiments of the disclosure will be described with reference to the accompanying drawings.

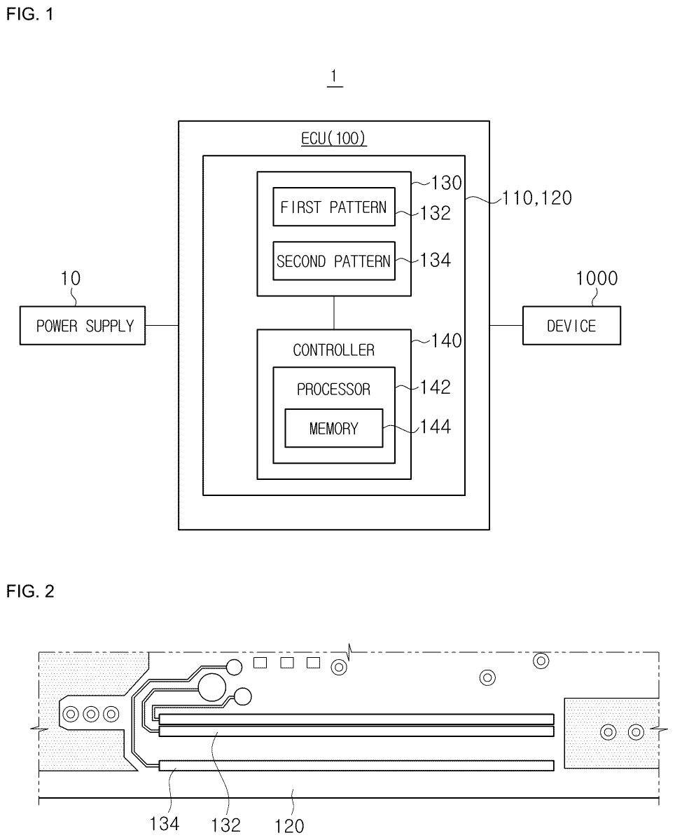

FIG. 1 is a block diagram of a vehicle in accordance with one embodiment of the present disclosure.

FIG. 2 is a diagram illustrating a first pattern and a second pattern on a circuit board in accordance with one embodiment of the present disclosure.

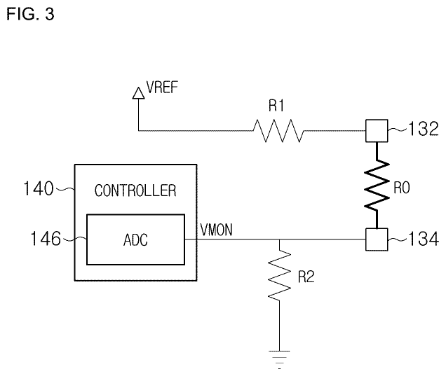

FIG. 3 is a diagram illustrating a circuit configuration of an electronic control unit in accordance with one embodiment of the present disclosure.

Referring to FIG. 1, a vehicle 1 may include a power supply 10, an electronic control unit (ECU) 100, and/or one or more devices 1000.

The power supply 10 may supply power to the vehicle 1 and may include, for example, a battery (not shown).

The power supply 10 may supply power to the ECU 100.

The ECU 100 may control the vehicle 1, for example, a brake system (not shown) of the vehicle 1.

For example, the ECU 100 may be installed inside an engine room (not shown) of the vehicle 1.

The ECU 100 may include a housing 110 and a circuit board 120 installed inside the housing 110.

The housing 110 may protect the circuit board 120 therein and may be fabricated in various forms.

For example, the circuit board 120 may be a printed circuit board (PCB).

The circuit board 120 may have a pattern 130 disposed thereon and which may be used to determine (also referred to as detect) whether a substance has flowed into the housing 110 and/or to determine the type of substance that has flowed into the housing 110.

For example, the pattern 130 may be disposed on an outer periphery of the circuit board 120.

The pattern 130 may be made of a material having electrical conductivity, for example, copper (Cu).

The pattern 130 may include at least one of a first pattern 132 (or also referred to as a reference pattern) and a second pattern 134 (or also referred to as a monitoring pattern).

Referring to FIG. 2, each of the first pattern 132 and the second pattern 134 may include a linear pattern extending in a first direction along an edge of the circuit board 120.

In addition, the first pattern 132 and the second pattern 134 may be parallelly disposed on the circuit board 120 with a predetermined interval therebetween.

A width of each of the first pattern 132 and the second pattern 134 may be determined according to a rated current of an analog to digital converter (ADC) 142 of a controller 140. For example, the width of each of the first pattern 132 and the second pattern 134 may be 0.5 mm, which may change.

A separation distance I (or also referred to as a pattern interval) between the first pattern 132 and the second pattern 134 may be determined by Equation 1 below such that a certain amount of resistance R is generated between the first pattern 132 and the second pattern 134 assuming that a substance is applied between the first pattern 132 and the second pattern 134,

$$l = \sqrt{\frac{RV}{ρ}} \qquad [ Equation 1 ]$$

(I: pattern interval, R: resistance,

$$R = ρ \frac{l}{S} = ρ \frac{{l}^{2}}{V} ,$$

ρ: resistivity of a substance (the resistivity has been determined for each substance), s: substance area, V: substance volume).

On the circuit board 120, the controller 140 capable of controlling the operation of the vehicle 1, for example, the brake system (not shown) of the vehicle 1 may be mounted.

The controller 140 may include a processor 142 that may control the operation of the ECU 100.

For example, the processor 142 may include a memory 144 that stores or memorizes programs and data for implementing the operation of controlling the ECU 100.

The memory 144 may provide the stored program and data to the processor 142 and memorize temporary data generated during the operation of the processor 142.

For example, the memory (not shown) may include a volatile memory, such as a static random access memory (SRAM), a dynamic random access memory (DRAM), and a non-volatile memory, such as a read-only memory (ROM), an erasable programmable read only memory (EPROM), an electrically erasable programmable read only memory (EEPROM), and a flash memory.

Although not shown in the drawing, the first pattern 132 of the ECU 100 may be electrically connected to a first power supply line (not shown) of the power source supplied from the power supply 10. In addition, the controller 140 may be electrically connected to a second power supply line (not shown) of the power source supplied from the power supply 10. In addition, the second pattern 134 may be electrically connected to the controller 140.

For example, a circuit configuration of the ECU 100 may be as shown in FIG. 3.

Referring to FIG. 3, the first pattern 132 of the ECU 100 may be a pattern for outputting a reference voltage VREF, and the second pattern 134 may be a pattern for monitoring a voltage of a circuit electrically connected to the second pattern 134.

The first pattern 132 may be connected in series with a resistor R1 on the first power supply line of the power source.

The second pattern 134 may be connected to the ADC 142 of the controller 140. In addition, the second pattern 134 may be electrically connected to a pull-down circuit.

For example, the pull-down circuit may be implemented by connecting the second pattern 134 to a ground GND through a resistor R2 such that a voltage of the pull-down circuit is detected as 0 V in a normal situation in which no substance has flowed into the housing 110.

When a substance, for example, moisture is flowed into the housing 110, a resistance R0 may be generated between the first pattern 132 and the second pattern 134. When the resistance R0 is generated between the first pattern 132 and the second pattern 134, the voltage of the second pattern 134 is matched to the reference voltage VREF, so that a voltage of the circuit electrically connected to the second pattern 134, e.g., a voltage VMON of the pull-down circuit, may be triggered to transition from 0 V to a voltage of a specific magnitude greater than 0 V.

That is, it may be seen that the voltage VMON of the pull-down circuit is greater than or equal to a certain voltage by the resistance formed between the first pattern 132 and the second pattern 134 due to the inflow of the substance into the housing 110.

Thus, the controller 140 may determine whether a substance has flowed into the housing 110 based on monitoring the voltage of the circuit electrically connected to the second pattern 134, e.g., the voltage VMON of the pull-down circuit, while power source is being supplied from the power supply 10.

For example, the controller 140 may control such that the first pattern 132 outputs a voltage of a predetermined magnitude, that is, a constant voltage, based on the power supply.

The controller 140 may monitor whether the voltage VMON of the pull-down circuit electrically connected to the second pattern 134 is greater than or equal to a predetermined reference voltage while the first pattern 132 is controlled to output the constant voltage.

When the voltage VMON of the pull-down circuit electrically connected to the second pattern 134 is greater than or equal to the predetermined reference voltage, the controller 140 may determine that a substance has flowed into the housing 110.

The controller 140 may control the voltage output of the first pattern 132 based on the determination of the inflow of the substance into the housing 110.

The controller 140 may monitor a voltage of the circuit electrically connected to the second pattern 134, for example, the voltage VMON of the pull-down circuit while controlling the voltage output of the first pattern 132, determine the type of the substance flowed into the housing 110 based on data obtained from the monitoring, and output corresponding information to the one or more devices 1000.

For example, controlling the voltage output of the first pattern 132 may include controlling a magnitude of the voltage of the first pattern 132 to be changed and output, and/or controlling a frequency of the voltage of the first pattern 132.

The controller 140 may control the magnitude of the voltage of the first pattern 132 to be changed and output so that the frequency of the voltage of the first pattern 132 is sequentially increased to a predetermined first range and then sequentially decreased to a predetermined second range.

The controller 140 may obtain a voltage level of the voltage VMON of the pull-down circuit electrically connected to the second pattern 134 based on the monitoring of the voltage VMON of the pull-down circuit electrically connected to the second pattern 134 while controlling the voltage of the first pattern 132 to be changed and output.

Alternatively, the controller 140 may control the frequency of the voltage of the first pattern 132 such that the frequency of the voltage of the first pattern 132 is sequentially increased to a predetermined range, while controlling such that the magnitude of the voltage of the first pattern 132 is changed and output so that the frequency of the voltage of the first pattern 132 is sequentially increased to a predetermined first range and then sequentially decreased to a predetermined second range.

The controller 140 may obtain the voltage level of the voltage VMON of the pull-down circuit electrically connected to the second pattern 134 by monitoring the voltage VMON of the pull-down circuit electrically connected to the second pattern 134 while controlling the frequency of the voltage of the first pattern 132 by controlling the magnitude of the voltage of the first pattern 132 changed and output. In addition, the controller 140 may generate a spectrum of the voltage level based on the voltage level.

The controller 140 may determine the type of the substance flowed into the housing 110 based on the obtained voltage level and/or the obtained spectrum of the voltage level.

Reference data corresponding to each of a plurality of predetermined substances, for example, aluminum powder, salt water, water, washer fluid, and/or brake oil, may be stored in advance in the memory 144. For example, the reference data corresponding to each of the plurality of substances may include a reference voltage level and/or a reference spectrum of the reference voltage level.

Accordingly, the controller 140 may determine the type of the substance flowed into the housing 110 based on the data obtained by monitoring the voltage of the pull-down circuit electrically connected to the second pattern 134 while controlling the voltage output of the first pattern 132, and the reference voltage-related data corresponding to each of the plurality of substances stored in the memory 144.

For example, the controller 140 may identify reference data, which matches the data obtained from the monitoring, among the reference data corresponding to each of the plurality of substances, and determine that the substance corresponding to the identified reference data is the substance having the type of the substance flowed into the housing 110.

The controller 140 may output, to the outside, information indicating that a substance has flowed into the housing 110 and/or information indicating the type of the substance flowed into the housing 110.

For example, the controller 140 may output the information to the one or more devices 1000 of the vehicle 1 through a communication circuit (e.g., a controller area network (CAN) communication circuit (not shown)).

For example, the one or more devices 1000 may include an output device (e.g., a speaker, a display, a warning light, and/or an indicator light) (not shown) of the vehicle 1 and/or a main control device (not shown) of the vehicle 1, and the like.

Upon receiving the information indicating that a substance has flowed into the housing 110 and the information indicating the type of the substance flowed into the housing 110, the output device of the vehicle 1 may output corresponding information.

Upon receiving the information indicating that a substance has flowed into the housing 110 and the information indicating the type of the substance flowed into the housing 110, the main control device of the vehicle 1 may control the interruption of the supply of power to the ECU 100 depending on the type of the substance flowed into the housing 110.

Meanwhile, the reference data corresponding to each of the plurality of substances stored in the memory 144 in the above-described embodiment may be determined through the following test processes.

First, when the ECU 100 is installed inside the engine room of the vehicle 1, brake oils (a first brake oil of DOT-3 standard and a second brake oil of DOT-4 standard), engine oil, transmission oil, steering oil, washer fluid, water, salt water, and aluminum powder were selected as substances that may be flowed into the ECU 100.

The selection of the brake oils (the first brake oil of DOT-3 standard and the second brake oil of DOT-4 standard), the engine oil, the transmission oil, the steering oil, and the washer fluid took into account the fact that they may leak from a reservoir tank inside the engine room of the vehicle 1. In addition, the selection of the water and the salt water takes into account that they may actually be flowed from the outside. Further, the selection of the aluminum powder takes into account that it may be generated during the production process of the ECU 100.

Thereafter, each of the selected substances was applied to a test circuit board designed to correspond to FIG. 3, and a plurality of substances, which serve as a reference for determining the substance that has flowed into the housing 110, are determined through an experiment of monitoring a voltage of a second test pattern corresponding to the second pattern 134 while applying a voltage to a first test pattern corresponding to the first pattern 132.

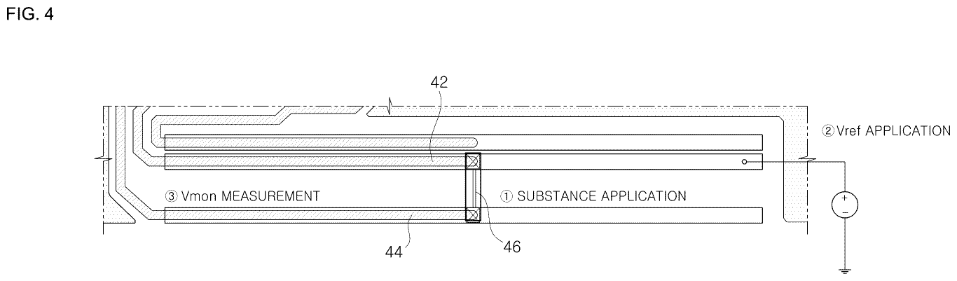

FIG. 4 is a diagram illustrating the first test pattern and the second test pattern on the test circuit board in accordance with one embodiment of the present disclosure.

Referring to FIG. 4, after applying (\textcircled{1}) each of selected substances 46 between a first test pattern 42 and a second test pattern 44, a voltage Vmon at the second test pattern 44 side, i.e., a circuit electrically connected to the second test pattern 44, was measured (\textcircled{3}) through a voltage measuring device (not shown) while applying (\textcircled{2}) a voltage Vref to the first test pattern 42.

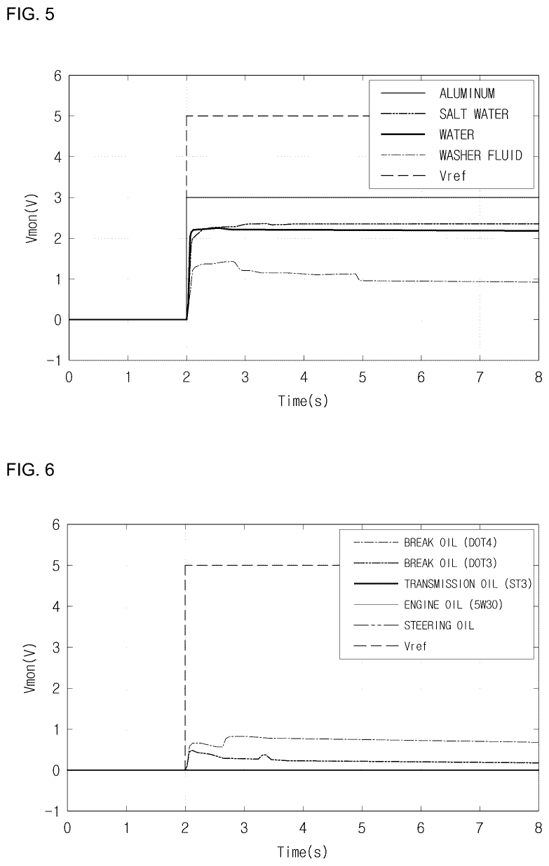

FIGS. 5 and 6 are diagrams illustrating voltage waveforms on the circuit electrically connected to the second test pattern for each substance when a reference voltage of a predetermined magnitude is applied to the first test pattern on the test circuit board in accordance with one embodiment of the present disclosure. In FIGS. 5 and 6, the horizontal axis represents time and the vertical axis represents the voltage Vmon at the second test pattern 44 side.

Referring to FIG. 5, after applying 1 mL of each of the selected substances between the first test pattern 42 and the second test pattern 44, the voltage Vmon at the second test pattern 44 side was measured through the voltage measuring device while allowing a constant voltage of about 5 V to be output from the first test pattern 42.

In the case of the aluminum powder, the salt water, the water, and the washer fluid, which are substances other than the oils, a voltage of 1V or more was measured as shown in FIG. 5, and it was found that there is a difference in intensity for each substance.

For example, the reference voltage Vref of a predetermined magnitude was applied to the first test pattern 42, and it was found that the voltage waveforms as shown in FIG. 5 were respectively generated for the aluminum powder, the salt water, the water, and the washer fluid.

Referring to FIG. 5, it was found that the voltage magnitudes were obtained in the following order: aluminum>salt water>water>washer fluid>DOT-4>DOT-3, i.e., response sensitivity was greater in the above order.

Further, after applying each of the brake oils (the first brake oil of DOT-3 standard and the second brake oil of DOT-4 standard), the engine oil, transmission oil, and the steering oil, the voltage Vmon at the second test pattern 44 side was measured through the voltage measuring device.

Referring to FIG. 6, it was found that, in the case of the transmission oil, the engine oil, and the steering oil, the voltage Vmon was nearly 0 V, that is, there was almost no response sensitivity. On the other hand, the effective voltage Vmon greater than 0 V was obtained for the brake oils (the first brake oil of DOT-3 standard and the second brake oil of DOT-4 standard), and the intensity of each of the brake oils (the first brake oil of DOT-3 standard and the second brake oil of DOT-4 standard) was found to be lower than those of the aluminum powder, the salt water, the water, and the washer fluid.

Through such a test, it was found that substances with lubricating properties, such as the engine oil, the transmission oil, and the steering oil, have significantly lower ionic mobility and thus are almost non-conductive.

Thus, in the disclosed disclosure, the engine oil, the transmission oil, and the steering oil are considered as substances that do not cause an electrical short circuit, and thus, the engine oil, the transmission oil, and the steering oil are not included in the plurality of substances serving as a reference for determining the substance flowed into the housing 110.

In addition, the aluminum powder was found to be highly conductive and had an effect of disconnecting two patterns, and thus not included in the plurality of substances used to determine the plurality of substances serving as a reference for determining the substance flowed into the housing 110.

Accordingly, excluding the engine oil, the transmission oil, the steering oil, and the aluminum powder, the brake oils (the first brake oil of DOT-3 standard and the second brake oil of DOT-4 standard), the washer fluid, the water, and the salt water were determined as the plurality of substances serving as a reference for determining the substance flowed into the housing 110.

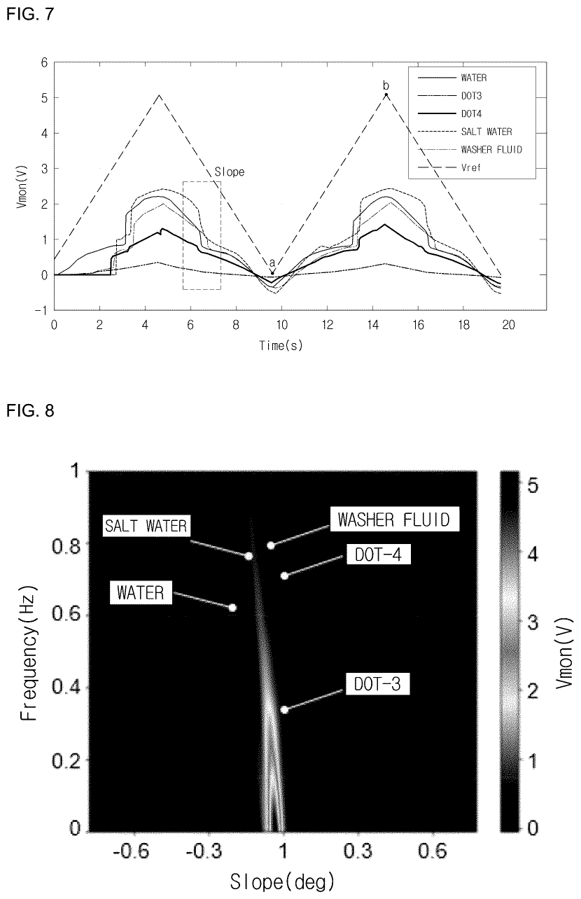

For each of the plurality of substances serving as a reference for determining the substance flowed into the housing 110, i.e., the brake oils (the first brake oil of DOT-3 standard and the second brake oil of DOT-4 standard), the washer fluid, the water, and the salt water, as shown in FIG. 7, the reference voltage Vref was allowed to be output from the first test pattern 42 in order to confirm that the voltage Vref of the first test pattern 42 follows the voltage Vmon at the second test pattern 44 side.

FIG. 7 is a diagram illustrating voltage waveforms on the circuit electrically connected to the second test pattern for each of the plurality of substances upon controlling the voltage magnitude of the first test pattern on the test circuit board in accordance with one embodiment of the present disclosure. In FIG. 7, the horizontal axis represents time and the vertical axis represents the voltage Vmon at the second test pattern 44 side.

Referring to FIG. 7, in a state in which each of the plurality of substances is applied between the first test pattern 42 and the second test pattern 44, the magnitude of the voltage Vref of the first test pattern 42 is adjusted such that the magnitude of the voltage Vref of the first test pattern 42 is sequentially increased to a predetermined first range and then sequentially decreased to a predetermined second range.

For example, as shown in FIG. 7, the voltage Vmon at the second test pattern 44 side was obtained through the voltage measuring device while changing the voltage Vref of the first test pattern 42 from 0 V to 5 V at a rate of 1 V/sec and again from 5 V to 0 V at a rate of 1 V/sec, and responsiveness was checked for whether the voltage Vref on the first test pattern 42 follows the voltage Vmon at the second test pattern 44 side.

When peak points of the voltage Vref of the first test pattern 42 are referred to as “a” and “b,” respectively, voltage values at points a and b for each substance were as shown in Table 1 below.

TABLE 1

| | Water | | DOT-3 | | DOT-4 | | Salt water | | Washer fluid | |
|---|---|---|---|---|---|---|---|---|---|---|
| Point a | −0.32 | V | 0 | V | −0.19 | V | −0.5 | V | −0.37 | V |
| Point b | 2.2 | V | 0.4 | V | 1.3 | V | 2.4 | V | 1.9 | V |

Referring to FIG. 7 and Table 1, it may be seen that at point a, the reverse voltage was measured for all substances except for the DOT-3 substance, whereas for the DOT-3 substance, the voltage was measured to be 0 V, which matches the voltage Vref of the first test pattern 42, and thus the DOT-3 substance was distinguished from the other substances.

Further, when comparing voltage values at point b for the substances other than the DOT-3 substance, an intensity and sharpness of the voltage could be used to distinguish between the substances, but the differences are subtle, making accurate distinction difficult.

Accordingly, in order to clearly distinguish the substances from each other, data on the voltage Vmon at the second test pattern 44 side was obtained for each substance through the voltage measuring device while adjusting a changing frequency of the reference voltage Vref of the first test pattern 42 to be gradually increased. Further, the voltage waveforms were plotted as frequency-independent spectra as shown in FIG. 8, so that characteristic of each of the substances is better visualized.

Referring to FIG. 7, it may be seen that while the voltage Vmon at the second test pattern 44 side is increased or decreased, a slope of the voltage Vmon at the second test pattern 44 side is rapidly increased or decreased at a specific voltage of the first test pattern 42, that is, the specific reference voltage Vref.

For example, it may be seen that the slope of the voltage Vmon at the second test pattern 44 side is rapidly decreased in section Slope of FIG. 7.

A variation cycle the voltage Vref of the first test pattern 42 was further increased by utilizing these ionic properties, so that the differences in characteristics between the substances became apparent. In addition, the spectrum as shown in FIG. 8 was plotted for each of the substance, the salt water, the washer fluid, the water, the DOT-3, and the DOT-4, wherein the spectrum includes “Slope” that is a slope variable of the voltage Vmon at the second test pattern 44 side relative to the voltage Vref of the first test pattern 42.

FIG. 8 is a diagram illustrating a spectrum for each of the plurality of substances upon controlling a voltage frequency of the first test pattern on the test circuit board in accordance with one embodiment of the present disclosure.

Referring to FIG. 8, it may be seen that in a relatively low frequency region, a slope of each of the substances, i.e., the washer fluid, the salt water, the water, the DOT-4, and the DOT-3 is similar to each other, making it difficult to distinguish the substances, but in a relatively high frequency region, the higher the conductivity of the substance, the sharper the voltage Vmon at the second test pattern 44 side, making it possible to distinguish the substances.

Through the test described above, substances that are likely to cause a short circuit of the ECU 100 were determined, and it was found that liquids with lubricating properties, such as the transmission oil, the engine oil, and the steering oil, do not have conductivity and are not likely to cause the short circuit in the ECU 100.

In addition, the voltage data at the second test pattern 44 side for each substance in FIG. 7, the voltage data at points a and b for each substance in Table 1, and/or the spectrum for each substance in FIG. 8 obtained through the test described above can be stored in the memory 144 as back data, which is reference data corresponding to each of the plurality of substances.

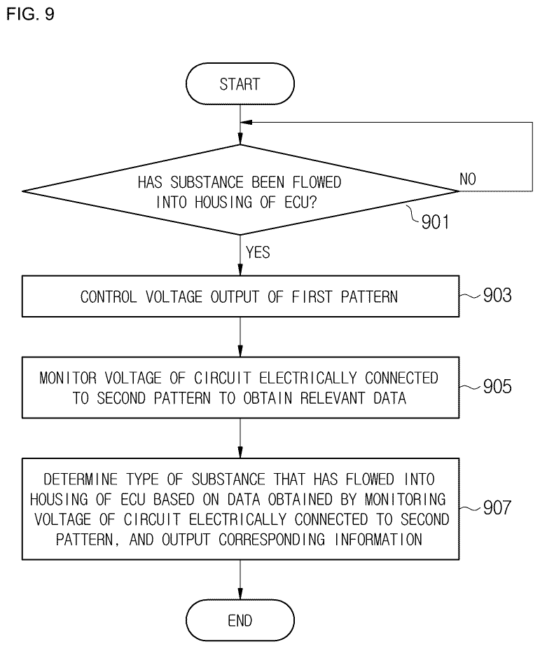

FIG. 9 is a flowchart of an operation of the ECU 100 and/or the controller 140 in accordance with one embodiment of the present disclosure.

Referring to FIG. 9, the ECU 100 may determine whether a substance has flowed into the housing 110 of the ECU 100 (901).

The ECU 100 may control such that the first pattern 132 outputs a voltage of a predetermined magnitude (for example, 5 V) for a predetermined period of time based on the supply of power from the power supply 10.

The ECU 100 may monitor whether a voltage of a circuit electrically connected to the second pattern 134 is greater than or equal to a predetermined reference voltage, which is greater than 0 V, while controlling such that the first pattern 132 outputs the voltage of the predetermined magnitude.

The ECU 100 may determine that a substance has been flowed into the housing 110 when the voltage of the circuit electrically connected to the second pattern 134 is greater than or equal to the predetermined reference voltage, and may otherwise determine that a substance has not been flowed into the housing 110.

When the ECU 100 determines that a substance has flowed into the housing 110 of the ECU 100, the ECU 100 may perform operation 903 and otherwise perform operation 901 again.

The ECU 100 may control the output of a voltage VREF of the first pattern 132 (903).

The ECU 100 may control the output of the voltage VREF of the first pattern 132 such that the voltage VREF of the first pattern 132 is sequentially increased to a predetermined first voltage value and then sequentially reduced to a predetermined second voltage value as in a voltage Vref of the first test pattern 42 of FIG. 7. For example, the ECU 100 may control the output of the voltage VREF of the first pattern 132 such that a voltage in the form of a triangle wave or a sine wave is output.

Further, the ECU 100 may control the output of the voltage VREF of the first pattern 132 such that a frequency of the voltage VREF is sequentially increased to a predetermined range.

While controlling the voltage output of the first pattern 132, the ECU 100 may monitor a voltage VMON of the circuit electrically connected to the second pattern 134 to obtain relevant data (905).

While controlling the voltage output of the first pattern 132, the ECU 100 may obtain a voltage level of the circuit electrically connected to the second pattern 134 and/or generate a spectrum of the voltage level.

The ECU 100 may determine a type of the substance that has flowed into the housing 110 of the ECU 100 based on the data obtained by monitoring the voltage VMON of the circuit electrically connected to the second pattern 134, and output corresponding information (907).

The ECU 100 may determine the type of the substance that has flowed into the housing 110 of the ECU 100 based on reference data stored in the memory 144 and the obtained data.

For example, the reference data stored in the memory 144 may store data on the voltage level for each of a plurality of substances as shown in FIG. 7, and/or data on the spectrum of the voltage level for each of the plurality of substances as shown in FIG. 8.

The ECU 100 may identify the reference data, which matches the voltage level of the circuit electrically connected to the second pattern 134 and/or the spectrum of the voltage level obtained during the voltage control of the first pattern 132, from among the reference data of each of the plurality of substances stored in the memory 144.

In addition, the ECU 100 may determine the substance corresponding to the identified reference data using the type of the substance flowed into the housing 110 of the ECU 100, and output information indicating the type of the substance flowed into the housing 110 to the one or more devices 1000.

Meanwhile, in addition to the above-described embodiment, the result of determining whether a substance has flowed into the housing 110 of the ECU 100 according to operation 901 described above may be output to the one or more electronic devices 1000.

The ECU 100 and the method for determining a substance flowed into the ECU 100 according to the embodiments described above may determine the inflow of the substance into the ECU 100 of the vehicle 1 and the type of the substance flowed into the ECU 100, and provide corresponding information.

For example, the ECU 100 and the method for determining a substance flowed into the ECU 100 may determine what type of substance is flowed into the housing 110 of the ECU 100 by analyzing a voltage level and/or a spectrum of the voltage level of the circuit electrically connected to the second pattern 134.

In addition, the ECU 100 and the method for determining a substance flowed into the ECU 100 can help reduce the risk of an accident of the vehicle 1 due to malfunction of the ECU 100 by providing information on the substance flowed into the housing of the ECU 100 to the one or more devices 1000.

Meanwhile, the disclosed embodiments may be implemented in the form of a recording medium that stores instructions executable by a computer. The instructions may be stored in the form of program codes, and when executed by a processor, the instructions may perform operations of the disclosed embodiments by generating a program module. The recording medium may be implemented as a computer-readable recording medium.

The computer-readable recording medium may include all kinds of recording media storing instructions that can be interpreted by a computer. For example, the computer-readable recording medium may be Read Only Memory (ROM), Random Access Memory (RAM), a magnetic tape, a magnetic disc, flash memory, an optical data storage device, etc.

A machine-readable storage medium may be provided in the form of a non-transitory storage medium, wherein the term ‘non-transitory’ simply means that the storage medium is a tangible device, and does not include a signal (e.g., an electromagnetic wave), but this term does not differentiate between where data is semi-permanently stored in the storage medium and where the data is temporarily stored in the storage medium.

So far, the disclosed embodiments have been described with reference to the accompanying drawings. It will be understood by one of ordinary skill in the technical art to which the disclosure belongs that the disclosure can be embodied in different forms from the disclosed embodiments without changing the technical spirit and essential features of the disclosure. Thus, it should be understood that the disclosed embodiments described above are merely for illustrative purposes and not for limitation purposes in all aspects.

What is claimed is:

1. An electronic control unit comprising:
a housing;
a circuit board disposed inside the housing and including a first pattern and a second pattern, wherein the first pattern and second pattern of the circuit board are spaced apart from each other and disposed parallel to each other; and
a controller mounted on the circuit board,
wherein the controller is configured to:
control an output of a voltage of the first pattern of the circuit board depending on whether a substance is flowed into an inside of the housing;
monitor a voltage of a circuit electrically connected to the second pattern of the circuit board while controlling the output of the voltage of the first pattern of the circuit board; and
determine a type of the substance flowed into the inside of the housing based on the monitored voltage of the circuit electrically connected to the second pattern of the circuit board.

2. The electronic control unit of claim 1, further comprising a memory configured to store reference data including at least one of a reference voltage level corresponding to each of a plurality of predetermined substances or a spectrum of the reference voltage level,
wherein the controller is configured to determine the type of the substance flowed into the inside of the housing using the reference data stored in the memory.

3. The electronic control unit of claim 2, wherein the controller is configured to monitor the voltage of the circuit electrically connected to the second pattern of the circuit board while controlling the output of the voltage of the first pattern of the circuit board such that the voltage of the first pattern of the circuit board is increased to a predetermined first voltage value and then decreased to a predetermined second voltage value.

4. The electronic control unit of claim 3, wherein the controller is configured to monitor the voltage of the circuit electrically connected to the second pattern of the circuit board while controlling the output of the voltage of the first pattern of the circuit board and controlling the voltage of the first pattern of the circuit board such that a frequency of the voltage of the first pattern of the circuit board is increased to be within a predetermined range.

5. The electronic control unit of claim 4, wherein the controller is configured to determine the type of the substance flowed into the inside of the housing based on the voltage of the circuit electrically connected to the second pattern of the circuit board.

6. The electronic control unit of claim 5, wherein the controller is configured to determine the type of the substance flowed into the inside of the housing based on a spectrum of the voltage of the circuit electrically connected to the second pattern of the circuit board.

7. The electronic control unit of claim 1, wherein the controller is configured to control the output of the voltage of the first pattern of the circuit board to be a predetermined magnitude using supply of power from a power supply, monitor whether the voltage of the circuit electrically connected to the second pattern of the circuit board is greater than or equal to a predetermined reference voltage while controlling the output of the voltage of the first pattern of the circuit board to be the predetermined magnitude, and determine that the substance has flowed into the inside of the housing when the voltage of the circuit electrically connected to the second pattern of the circuit board is greater than or equal to the predetermined reference voltage.

8. The electronic control unit of claim 1, wherein the controller is configured to detect a voltage of the circuit, electrically connected to the second pattern of the circuit board, caused by a resistance formed between the first pattern and the second pattern of the circuit board due to the substance flowed into the inside of the housing.

9. The electronic control unit of claim 8, wherein:
the first pattern of the circuit board is electrically connected to a first power supply line of a power source,
the controller is electrically connected to a second power supply line of the power source and the second pattern of the circuit board, and
the circuit electrically connected to the second pattern of the circuit board comprises a pull-down circuit connected between the controller and the second pattern of the circuit board.

10. The electronic control unit of claim 1, wherein each of the first pattern and the second pattern of the circuit board includes a linear pattern extending along an edge of the circuit board.

11. The electronic control unit of claim 1, wherein the type of the substance includes at least one of salt water, water, washer fluid, brake oil, or oil.

12. A method for controlling an electronic control unit, the method comprising:
controlling an output of a voltage of a first pattern of a circuit board disposed inside a housing of the electronic control unit depending on whether a substance is flowed into an inside of the housing of the electronic control unit;
while controlling the output of the voltage of the first pattern of the circuit board, monitoring a voltage of a circuit electrically connected to a second pattern of the circuit board, wherein the first pattern and the second pattern of the circuit board are spaced apart from each other and disposed parallel to each other; and
determining a type of the substance flowed into the inside of the housing based on the monitored voltage of the circuit electrically connected to the second pattern of the circuit board.

13. The method of claim 12, wherein the determining of the type of the substance comprises determining the type of the substance flowed into the inside of the housing using reference data including at least one of a reference voltage level corresponding to each of a plurality of predetermined substances or a spectrum of the reference voltage level.

14. The method of claim 13, wherein the monitoring of the voltage of the circuit electrically connected to the second pattern of the circuit board is performed while controlling the output of the voltage of the first pattern of the circuit board such that the voltage of the first pattern of the circuit board is increased to a predetermined first voltage value and then decreased to a predetermined second voltage value.

15. The method of claim 14, wherein the monitoring of the voltage of the circuit electrically connected to the second pattern of the circuit board is performed while controlling the voltage of the first pattern of the circuit board such that a frequency of the voltage of the first pattern of the circuit board is increased to be within a predetermined range.

16. The method of claim 15, wherein the determining of the type of the substance flowed into the inside of the housing includes determining the type of the substance flowed into the inside of the housing based on the voltage of the circuit electrically connected to the second pattern of the circuit board.

17. The method of claim 16, wherein the determining of the type of the substance flowed into the inside of the housing includes determining the type of the substance flowed into the inside of the housing based on a spectrum of the voltage of the circuit electrically connected to the second pattern of the circuit board.

18. The method of claim 12, further comprising:
controlling the output of the voltage of the first pattern of the circuit board to be a predetermined magnitude using supply of power from a power supply;
monitoring whether the voltage of the circuit electrically connected to the second pattern of the circuit board is greater than or equal to a predetermined reference voltage while controlling the output of the voltage of the first pattern of the circuit board to be the predetermined magnitude; and
determining that the substance has flowed into the inside of the housing when the voltage of the circuit electrically connected to the second pattern of the circuit board is greater than or equal to the predetermined reference voltage.

19. The method of claim 12, further comprising detecting a voltage of the circuit, electrically connected to the second pattern of the circuit board, caused by a resistance formed between the first pattern and the second pattern of the circuit board due to the substance flowed into the inside of the housing.

20. The method of claim 19, wherein:
the first pattern of the circuit board is electrically connected to a first power supply line of a power source,
the controller is electrically connected to a second power supply line of the power source and the second pattern of the circuit board, and
the circuit electrically connected to the second pattern of the circuit board comprises a pull-down circuit connected between the controller and the second pattern of the circuit board.
